(19) United States
(12) Patent Application Publication
(10) Pub. No.: US 2024/0319282 A1
(43) Pub. Date: Sep. 26, 2024

(54) ADAPTIVE STATE OF CHARGE CORRECTION AND ESTIMATION FOR A BATTERY PACK OF A FUEL CELL ELECTRIC VEHICLE

(71) Applicant: HYZON MOTORS USA INC., Bolingbrook, IL (US)

(72) Inventors: Asadullah Khalid, Bolingbrook, IL (US); Mark Michelotti, Buffalo Grove, IL (US)

(21) Appl. No.: 18/613,630

(22) Filed: Mar. 22, 2024

Related U.S. Application Data
(60) Provisional application No. 63/491,588, filed on Mar. 22, 2023.

(51) Int. Cl. G01R 31/3835; G01R 31/367; G01R 31/389

(52) U.S. Cl. CPC G01R 31/3835; G01R 31/367; G01R 31/389

(57) ABSTRACT

A method for providing an estimated present state of charge of a battery pack includes measuring battery parameters and then calculating a first state of charge utilizing an initial state of charge and the battery parameters. An error covariance prediction is calculated for the calculated first state of charge. A correction of the first state of charge is determined by mapping the open circuit voltage of the battery to the initial state of charge to obtain an open circuit voltage-initial state of charge confidence slope, calculating a Kalman gain of the error covariance prediction, and mapping the open circuit voltage (incorporating EMF) to the first state of charge. The estimated present state of charge is calculated by correcting the first state of charge utilizing selected battery parameters, the Kalman gain, and the mapping of the resulting voltage of the battery to the first state of charge.

### CROSS-REFERENCE TO RELATED APPLICATIONS

This application claims the benefit of U.S. Provisional Application No. 63/491,588, filed on Mar. 22, 2023. The entire disclosure of the above application is incorporated herein by reference.

### FIELD

The present technology relates to batteries for a fuel cell electric vehicle, including methods and systems for providing an estimated state of charge of a battery pack for a fuel cell electric vehicle.

### INTRODUCTION

This section provides background information related to the present disclosure which is not necessarily prior art.

With the increased usage of lithium iron phosphate (LiFePO₄ or LFP) batteries in vehicular applications, effective and efficient management of its state of charge (SOC) has become vital. The open circuit voltage (OCV) curves of such chemistry present sudden ramp ups/downs (collectively termed ‘elbow regions’) corresponding to the battery's capacity or SOC. The OCV values of these elbow regions tend to change under charging/discharging scenarios. Moreover, SOC is typically computed within a battery management system (BMS) utilizing defined conventional approaches.

The defined conventional approaches used to compute SOC tend to ignore the internal dynamics of a battery system that reflect the actual working state of the battery. In addition, the conventional SOC computation approaches expect an external event, such as plug-in of an on-board charger (OBC) to perform correction or re-calibration of the SOC. This correction is mainly performed because the conventional SOC computation approaches, such as coulomb counting or an ampere-hour integral method, accumulates error over time due to multiple instances of crossing-over the elbow regions and is thus, unable to maintain and output accurate results. In addition, OBCs providing up to Level 2 charging (based on SAE J1772 standard) limit the charging current, while the battery pack maintains the capability to accept safe levels of charging currents beyond that limit. As a result, charging-rates (C-rate), and consequently frequency of SOC correction instances, are slowed down thus inadvertently delaying the charging and SOC correction processes.

Accordingly, there is a need for improved methods and systems for providing an estimated state of charge of a battery pack for a fuel cell electric vehicle.

### SUMMARY

In concordance with the instant disclosure, an adaptive state of charge correction and estimation method for a battery pack of a fuel cell electric vehicle, has surprisingly been discovered. The present technology includes articles of manufacture, systems, and processes that relate to provision of an estimated state of charge of a battery pack for a fuel cell electric vehicle. Ways of making and using an electrical storage system are provided and include use of an estimated present state of charge of a battery pack of multiple battery cells.

In certain embodiments, the present disclosure includes methods for providing an estimated present state of charge of a battery that may include measuring a battery parameter including an open circuit voltage, performing an estimation stage, and performing a correction stage. Performing the estimation stage may include a state prediction step and an error covariance step. The state prediction step may include calculating a first state of charge of the battery utilizing an initial state of charge of the battery and the battery parameter. The error covariance step may include calculating an error covariance prediction for the first state of charge of the battery.

Performing the correction stage may include an observation matrix update step, a Kalman gain step, an electromotive force mapping step, and a measurement estimate update step. The observation matrix update step may include mapping the open circuit voltage of the battery to the initial state of charge of the battery to obtain an open circuit voltage-initial state of charge confidence slope. The Kalman gain step may include calculating a Kalman gain of the error covariance prediction for the first state of charge of the battery utilizing the open circuit voltage-initial state of charge confidence slope. The electromotive force mapping step may include mapping the open circuit voltage including electromotive force to the first state of charge, and the measurement update step may include correcting the first state of charge utilizing the battery parameter, the Kalman gain of the error covariance prediction for the first state of charge of the battery, and the mapping the open circuit voltage to the first state of charge to provide the estimated present state of charge.

In certain embodiments, the present disclosure provides an electrical storage system that includes a battery pack including one or more battery cells. A sensor may be provided in electrical communication with the battery and configured to measure electrical parameters of the battery. The electrical storage system also includes a controller in electrical communication with the sensor. The controller may be configured to perform an estimation stage and perform a correction stage. Performing the estimation stage may include a state prediction step and an error covariance step. The state prediction step may include calculating a first state of charge of the battery utilizing an initial state of charge of the battery and the battery parameter. The error covariance step may include calculating an error covariance prediction for the first state of charge of the battery. Electrical storage systems can be operated using aspects of the methods provided by the present disclosure.

In certain embodiments, the present disclosure provides methods for providing an estimated present state of charge of a battery pack. Such methods may include measuring electrical parameters of a plurality of battery cells of the battery pack, where the electrical parameters of the plurality of battery cells may include an open circuit voltage, an ohmic resistance, a RC pair resistance, a RC pair capacitance, a voltage across a RC pair, a terminal voltage, and a fuel cell output current. A first state of charge for each battery cell of the plurality of battery cells may be calculated utilizing an initial state of charge and the electrical parameters. An error covariance prediction may be calculated for the first state of charge of each battery cell of the plurality of battery cells. An estimated present state of charge of each of the plurality of battery cells may be calculated by: mapping the open circuit voltage to the initial state of charge to obtain an open circuit voltage-initial state of charge confidence slope; calculating a Kalman gain of the error covariance prediction utilizing the open circuit voltage-initial state of charge confidence slope; mapping the open circuit voltage (incorporating EMF) to the first state of charge; and correcting the first state of charge of each battery cell of the plurality of battery cells by utilizing selected ones of the electrical parameters, and the Kalman gain, and the mapping of the resulting voltage to the first state of charge to provide the estimated present state of charge of each battery cell of the plurality of battery cells. The estimated present state of charge for each battery cell of the plurality of battery cells may be averaged to provide an estimated present state of charge of the battery pack. The error covariance prediction may be updated for each battery cell of the plurality of battery cells utilizing the Kalman gain for use in a subsequent iteration of the method. The estimated present state of charge of each battery cell of the plurality of battery cells may be used as the initial state of charge in a subsequent iteration of the method to provide the estimated present state of charge for the battery pack.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a flowchart illustrating a method for providing an estimated present state of charge of a battery pack, according to an embodiment of the present disclosure.

FIGS. 2A & 2B provide a flowchart illustrating a method for providing an estimated present state of charge of a battery pack, according to an embodiment of the present disclosure.

FIGS. 3A & 3B provide a schematic diagram further illustrating aspects of the method shown FIGS. 2A-2B for providing an estimated present state of charge of a battery pack, according to an embodiment of the present disclosure.

FIG. 4 shows a graphical representation of a charging and discharging OCV-SOC curve of a single battery cell exhibiting examples of elbow regions that are addressed by the systems and process of the present disclosure that estimate the present state of charge of a battery pack.

FIG. 5 is a schematic of a 1-RC battery model applied to the whole battery pack of N battery cells, being charged by a fuel cell.

FIG. 6 is a graphical representation of a confidence slope of OCV-SOC used to build an observation matrix.

FIG. 7 is a graphical representation of an ohmic resistance-temperature curve for the 1-RC battery model.

FIG. 8 is a graphical representation of a polarization resistance-temperature curve for the 1-RC battery model.

FIG. 9 is a graphical representation of a polarization capacitance-temperature curve for the 1-RC battery model.

FIG. 10 is a block diagram illustrating an electrical storage system, according to an embodiment of the present disclosure.

FIG. 11 is a flowchart illustrating a method for providing an estimated present state of charge of a battery pack, according to an embodiment of the present disclosure.

FIG. 12 is a graphical representation showing a case study 1 where an initial SOC was set at 35% with a current profile A over a period of 3600 seconds.

FIGS. 13-14B are graphical representations showing the case study 1 with the SOC profile A over the period of 3600 seconds. The SOC profiles at a second elbow region are shown in graphs 13-14B, according to an embodiment of the present disclosure.

FIG. 15 is a graphical representation showing the case study 1 illustrating an error profile over the period of 3600 seconds, according to an embodiment of the present disclosure.

FIG. 16 is a graphical representation showing a case study 2 where an initial SOC was set at 90% with a current profile B over a period of 1 hour, according to an embodiment of the present disclosure.

FIG. 17 is a graphical representation showing the case study 2 with the SOC of the current profile B over a period of 1 hour, according to an embodiment of the present disclosure.

FIG. 18 is a graphical representation showing the case study 2 with the error profile of the current profile B over a period of 1 hour, according to an embodiment of the present disclosure.

FIG. 19 is a graphical representation showing the case study 3 with the SOC of the current profile C over a period of 1 hour, according to an embodiment of the present disclosure.

FIG. 20 is a graphical representation showing the case study 3 with the error profile of the current profile C over a period of 1 hour, according to an embodiment of the present disclosure.

### DETAILED DESCRIPTION

The following description of technology is merely exemplary in nature of the subject matter, manufacture and use of one or more inventions, and is not intended to limit the scope, application, or uses of any specific invention claimed in this application or in such other applications as may be filed claiming priority to this application, or patents issuing therefrom. Regarding methods disclosed, the order of the steps presented is exemplary in nature, and thus, the order of the steps can be different in various embodiments, including where certain steps can be simultaneously performed, unless expressly stated otherwise. “A” and “an” as used herein indicate “at least one” of the item is present; a plurality of such items may be present, when possible. Except where otherwise expressly indicated, all numerical quantities in this description are to be understood as modified by the word “about” and all geometric and spatial descriptors are to be understood as modified by the word “substantially” in describing the broadest scope of the technology. “About” when applied to numerical values indicates that the calculation or the measurement allows some slight imprecision in the value (with some approach to exactness in the value; approximately or reasonably close to the value; nearly). If, for some reason, the imprecision provided by “about” and/or “substantially” is not otherwise understood in the art with this ordinary meaning, then “about” and/or “substantially” as used herein indicates at least variations that may arise from ordinary methods of measuring or using such parameters.

Although the open-ended term “comprising,” as a synonym of non-restrictive terms such as including, containing, or having, is used herein to describe and claim embodiments of the present technology, embodiments may alternatively be described using more limiting terms such as “consisting of” or “consisting essentially of.” Thus, for any given embodiment reciting materials, components, or process steps, the present technology also specifically includes embodiments consisting of, or consisting essentially of, such materials, components, or process steps excluding additional materials, components or processes (for consisting of) and excluding additional materials, components or processes affecting the significant properties of the embodiment (for consisting essentially of), even though such additional materials, components or processes are not explicitly recited in this application. For example, recitation of a composition or process reciting elements A, B and C specifically envisions embodiments consisting of, and consisting essentially of, A, B and C, excluding an element D that may be recited in the art, even though element D is not explicitly described as being excluded herein.

As referred to herein, disclosures of ranges are, unless specified otherwise, inclusive of endpoints and include all distinct values and further divided ranges within the entire range. Thus, for example, a range of “from A to B” or “from about A to about B” is inclusive of A and of B. Disclosure of values and ranges of values for specific parameters (such as amounts, weight percentages, etc.) are not exclusive of other values and ranges of values useful herein. It is envisioned that two or more specific exemplified values for a given parameter may define endpoints for a range of values that may be claimed for the parameter. For example, if Parameter X is exemplified herein to have value A and also exemplified to have value Z, it is envisioned that Parameter X may have a range of values from about A to about Z. Similarly, it is envisioned that disclosure of two or more ranges of values for a parameter (whether such ranges are nested, overlapping or distinct) subsume all possible combination of ranges for the value that might be claimed using endpoints of the disclosed ranges. For example, if Parameter X is exemplified herein to have values in the range of 1-10, or 2-9, or 3-8, it is also envisioned that Parameter X may have other ranges of values including 1-9, 1-8, 1-3, 1-2, 2-10, 2-8, 2-3, 3-10, 3-9, and so on.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

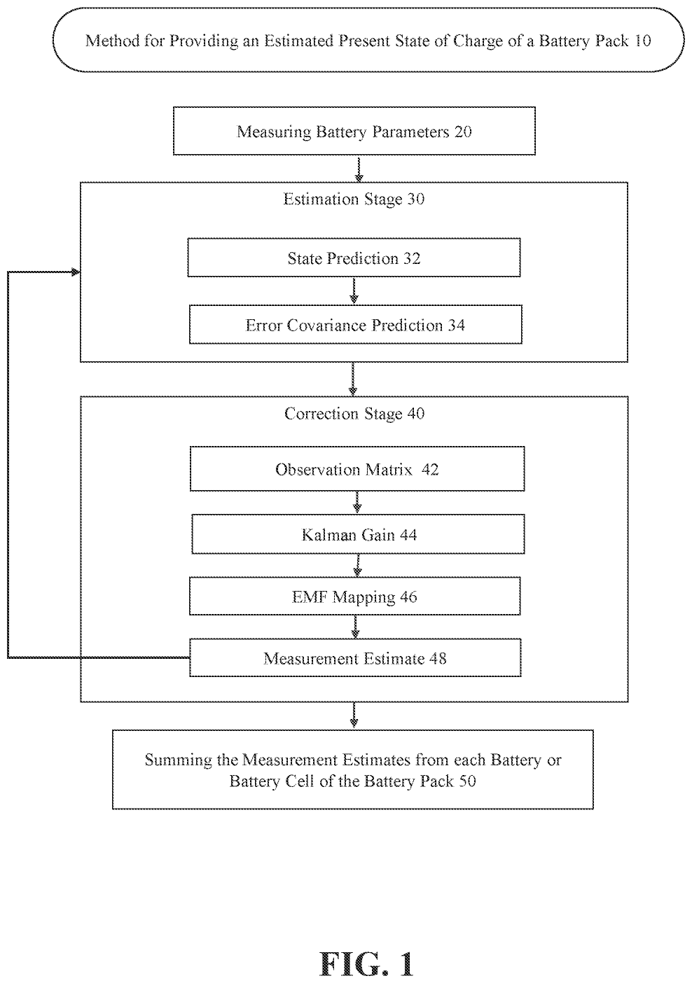

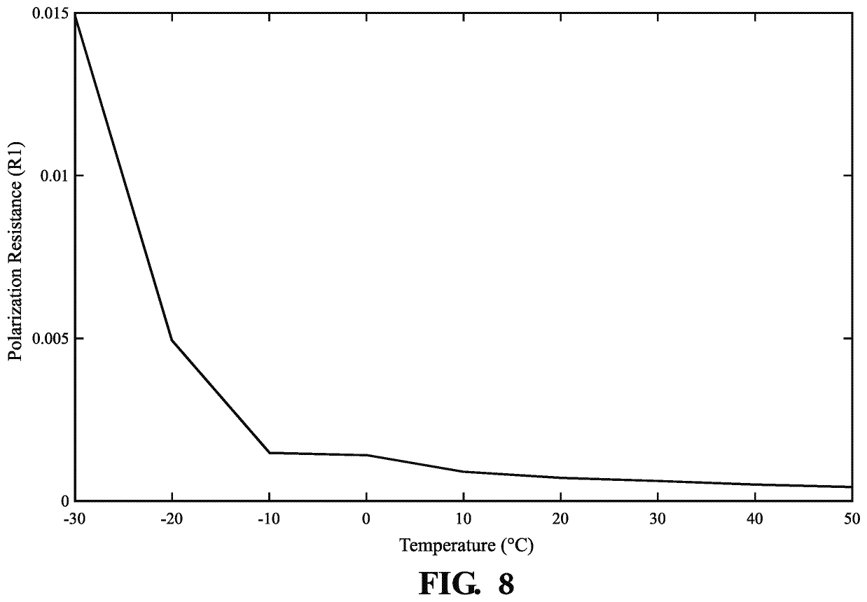

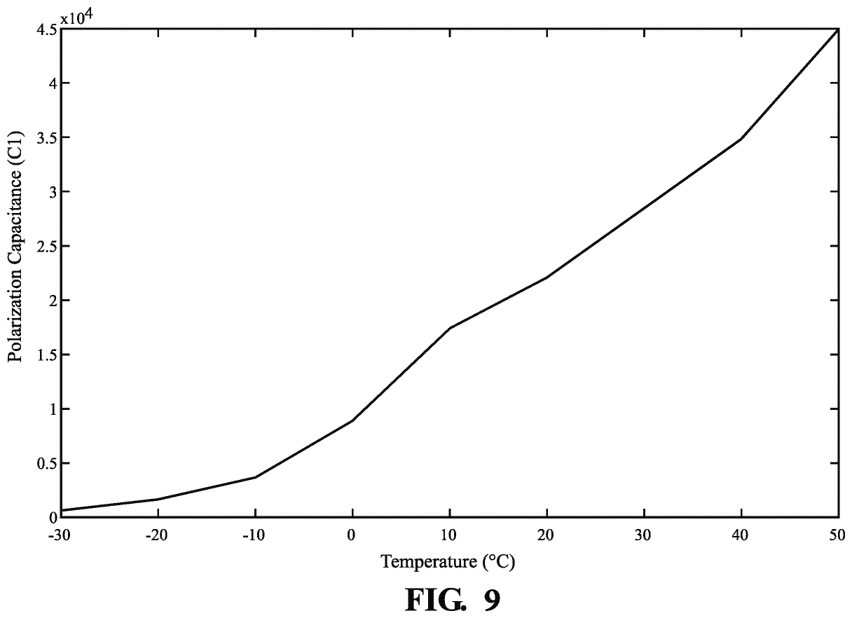

With reference now to the accompanying drawings, including FIGS. 1-11, certain aspects of an adaptive state of charge correction and estimation for a battery pack of a fuel cell electric vehicle and uses thereof are shown.

FIG. 1 is a flowchart representation of a method 10 for providing an estimated present state of charge of a battery pack, according to certain embodiments of the present disclosure. The method may include a step of measuring battery parameters 20 and an estimation stage 30 and a correction stage 40. The estimation stage 30 may include steps generally referenced as a state prediction step 32 where estimated SOC of the battery may be calculated, and an error covariance prediction step 34 where an uncertainty of the estimated SOC may be modeled. The correction stage 40 may include steps referenced as providing an observation matrix 42, a Kalman gain 44, electromotive force (EMF) mapping 46, and a measurement estimate 48. Then an observation matrix 42 may include where the SOC may be mapped to the measured values OCV-SOC slope, using the OCV-SOC confidence slope. The Kalman gain 44 may include where a Kalman gain may be calculated. The EMF mapping 46 may include mapping the electromotive force experienced. The measurement estimate 48 may include where certain measured battery parameters and outputs from the Kalman gain 44 and EMF mapping 46 are utilized to provide an estimated present state of charge of the battery pack as well as provide inputs to the error covariance prediction step 34 for use in a subsequent iteration of the method 10. The method 10 may also include a step 50 of averaging the measurement estimates from each battery or battery cell of a battery pack to provide an estimated charge of the battery pack. It should also be understood that the method 10 may be employed to continually monitor the battery pack and regularly update the estimated charge of the battery pack. Accordingly, the method may be typically performed at a specified interval to provide a real-time, or near real-time, estimated present state of charge of a battery pack, wherein results from one iteration of the method are used as inputs to the next iteration of the method.

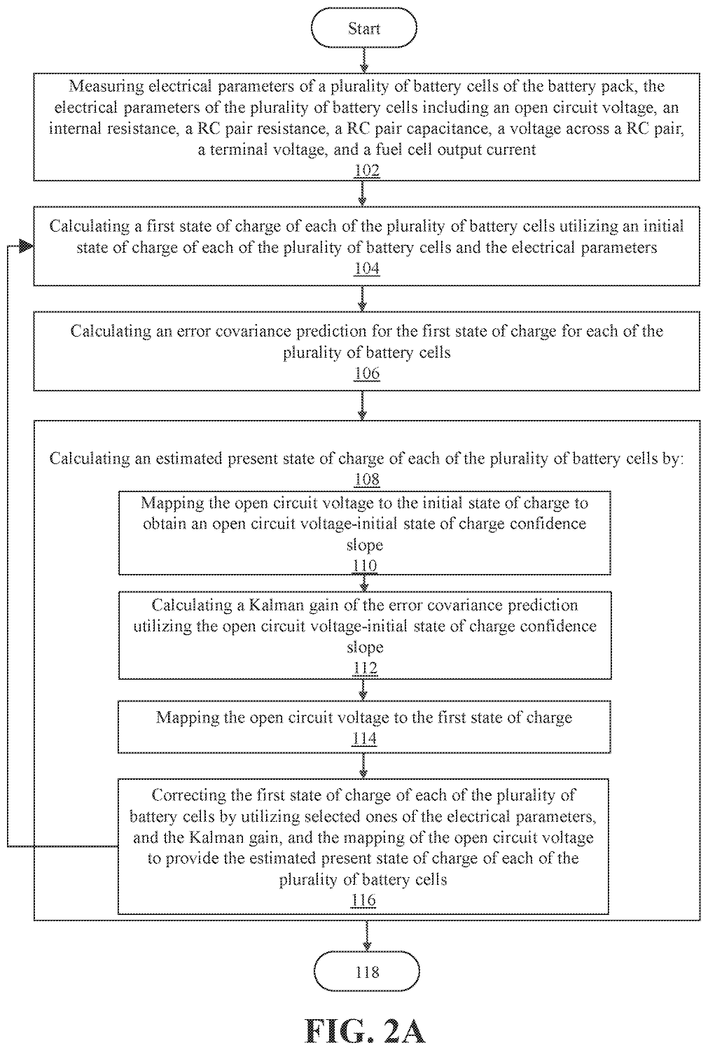

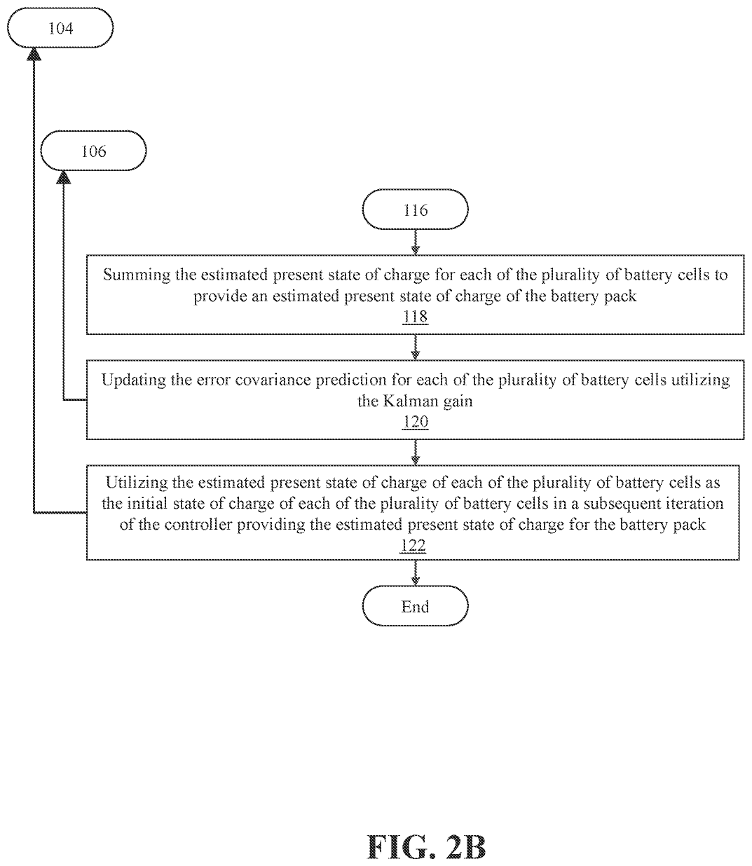

FIGS. 2A and 2B provide a flowchart relating to a method for providing an estimated present state of charge of a battery pack, according to another embodiment of the present disclosure. A measuring step 102 may include measuring electrical parameters of the battery or battery pack, or of each of a plurality of battery cells of the battery pack. The electrical parameters may include one or more of an open circuit voltage, an ohmic resistance, a resistor-capacitor (RC) pair resistance, a RC pair capacitance, a voltage across a RC pair, a terminal voltage, and a fuel cell output current. At step 104, the method may include calculating a first state of charge of each battery cell of the plurality of battery cells utilizing an initial state of charge of each battery cell of the plurality of battery cells and the electrical parameters. It should be understood that the first state of charge may be calculated for the overall battery pack as well as individual batteries in the battery pack, where the method may be employed at the overall battery pack level or the individual battery level, rather than on the level of each battery cell. At the error covariance prediction step 106, the method may include calculating an error covariance prediction for the first state of charge for each battery cell of the plurality of battery cells.

A correction stage step 108 may include a number of steps to calculate an estimated present state of charge of the battery pack, the battery, or individual battery cells by correcting the first state of charge provided by the estimation stage. The correction stage step 108 may include a mapping of the open circuit voltage to the initial state of charge to obtain an open circuit voltage-initial state of charge confidence slope 110. A Kalman gain of the error covariance prediction may be calculated utilizing the open circuit voltage-initial state of charge confidence slope at step 112. A mapping of the open circuit voltage (incorporating EMF) to the first state of charge may be carried out at step 114. The initial state of charge may be corrected at step 116 utilizing selected ones of the electrical parameters from the measuring step 102, the calculated Kalman gain 112, and the mapping of the resulting voltage to the first state of charge, where the corrected initial state of charge may be the estimated present state of charge of the battery pack, the battery, or individual battery cells.

At step 118, the method may further include averaging the estimated present state of charge for each of the plurality of batteries or battery cells of the battery pack to provide an estimated present state of charge of the battery pack. In certain embodiments, at step 120, the method may further include updating the error covariance prediction, where an update to the error covariance prediction step 106 may be provided for the battery pack, or the batteries or the battery cells of the battery pack. The update to the error covariance prediction step 106 may be made utilizing the Kalman gain. At step 122, the method may also include utilizing the estimated present state of charge of the battery pack, or the batteries or the battery cells of the battery pack as the initial state of charge thereof in a subsequent iteration of the providing the estimated present state of charge for the battery pack. It should be understood that the method may be employed to continually monitor the battery pack and regularly update the estimated charge of the battery pack. Accordingly, the method may be performed at a specified interval to provide a real-time, or near real-time, estimated present state of charge of the battery pack, where results from one iteration of the method are used as inputs to the next iteration of the method.

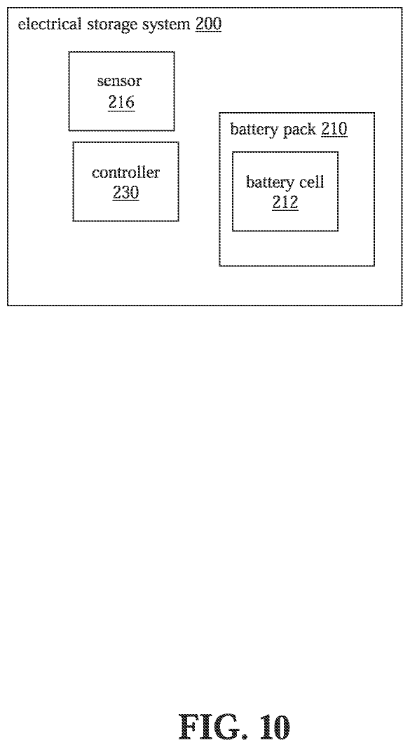

FIG. 10 is a block diagram that describes an electrical storage system 200, according to further embodiments of the present disclosure. The electrical storage system 200 may include a battery pack 210 having a single battery cell 212 or a plurality of battery cells. A sensor 216 or plurality of sensors may be provided that are in electrical communication with the battery cell 212 and configured to measure and/or acquire selected electrical parameters of the battery cell 212. Electrical parameters may include one or more of ohmic resistance, RC pair resistance, and RC pair capacitance, which may be obtained from cell level characterization sensors 216 and tests. The electrical storage system 200 may also include a controller 230 in electrical communication with the sensor 216. The controller 230 may be configured to carry out the method described herein for providing an estimated present state of charge of a battery pack. For example, the controller 230 may be configured to perform an estimation stage including a state prediction step including calculating a first state of charge of the battery utilizing an initial state of charge of the battery and the battery parameter and an error covariance step including calculating an error covariance prediction for the first state of charge of the battery.

The controller 230 may further be configured to perform a correction stage including an observation matrix update step including mapping an open circuit voltage of the battery to the initial state of charge of the battery to obtain an open circuit voltage-initial state of charge confidence slope, a Kalman gain step including calculating a Kalman gain of the error covariance prediction for the first state of charge of the battery utilizing the open circuit voltage-initial state of charge confidence slope, an electromotive force mapping step including mapping the open circuit voltage including electromotive force to the first state of charge, and a measurement estimate update step including correcting the first state of charge utilizing the battery parameter, the Kalman gain of the error covariance prediction for the first state of charge of the battery, and the mapping the open circuit voltage to the first state of charge to provide an estimated present state of charge.

In certain embodiments, the controller 230 may be configured to calculate a first state of charge of each battery cell 212 of a plurality of battery cells utilizing an initial state of charge and the electrical parameters. The controller 230 may calculate an error covariance prediction for the first state of charge of each battery cell 212 of the plurality of battery cells. The controller 230 may also be configured to calculate an estimated present state of charge of each battery cell 212 of the plurality of battery cells by: mapping the open circuit voltage to the initial state of charge to obtain an open circuit voltage-initial state of charge confidence slope; calculating a Kalman gain of the error covariance prediction utilizing the open circuit voltage-initial state of charge confidence slope; mapping the open circuit voltage incorporating EMF data, to the first state of charge; and correcting the estimated present state of charge of each battery cell 212 of the plurality of battery cells by correcting the first state of charge of each battery cell 212 of the plurality of battery cells utilizing selected ones of the electrical parameters, and the Kalman gain, and the mapping of the resulting voltage to the first state of charge to provide the estimated present state of charge of each battery cell 212 of the plurality of battery cells.

In certain embodiments, the estimated present state of charge of each battery cell 212 may be averaged to provide an estimated present state of charge of the battery pack 210. The electrical parameters may include one or more of an open circuit voltage, an ohmic resistance, a RC pair resistance, and a RC pair capacitance. The electrical parameters may also include one or more of a voltage across a RC pair, a terminal voltage, and a fuel cell output current.

In certain embodiments, the controller 230 may update the error covariance prediction for the battery cell 212 utilizing the Kalman gain. The estimated present state of charge of each battery cell 212 may be utilized as the initial state of charge of the battery cell 212, for example, where the battery cell 212 of the plurality of battery cells in a subsequent iteration of the controller 230 providing the estimated present state of charge for the battery pack 210. It should also be understood that the electrical storage system 200 may include a processor and a non-transient computer readable memory in electrical communication with the controller, sensors, and other systems to store and execute operating instructions, reference data, collected data, computational results, and the like. The electrical storage system 200 may also include input/output capabilities to facilitate the transferring of data and operating code, for example, to and from the electrical storage system 200.

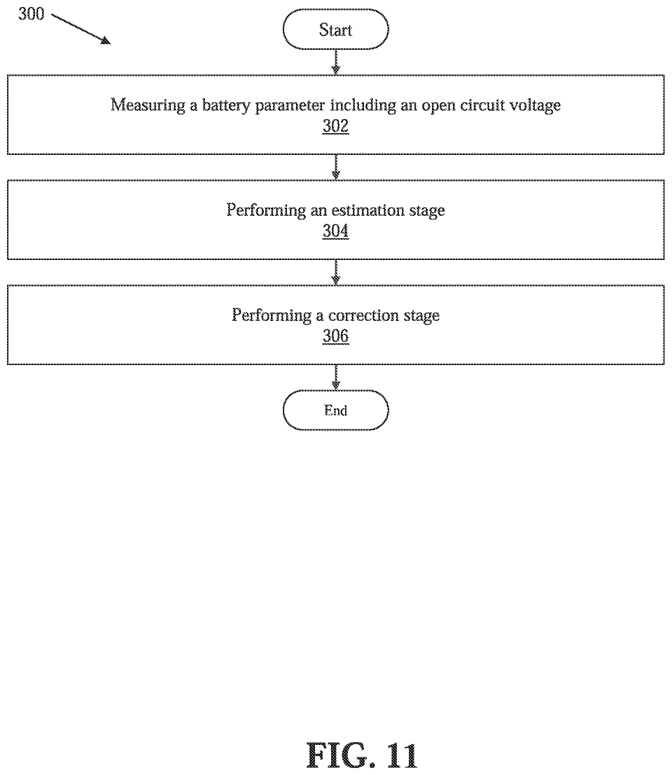

FIG. 11 is a flowchart illustrating aspects of a method 300 for providing an estimated present state of charge of a battery, including aspects as described herein and in accordance with certain embodiments of the present disclosure. The method 300 may be configured to provide an estimated present state of charge of a battery pack including measuring battery parameters and then calculating a first state of charge utilizing an initial state of charge and the battery parameters. In the step 302, a battery parameter including an open circuit may be measured. Then, in the step 304 an estimation stage may be performed. In certain embodiments, performing the estimation stage may include a state prediction step including calculating a first state of charge of the battery utilizing an initial state of charge of the battery and the battery parameter, and an error covariance step including calculating an error covariance prediction for the first state of charge of the battery. Then, in the step 306, a correction stage may be performed. The correction stage may include an observation matrix update step including mapping the open circuit voltage of the battery to the initial state of charge of the battery to obtain an open circuit voltage-initial state of charge confidence slope, a Kalman gain step including calculating a Kalman gain of the error covariance prediction for the first state of charge of the battery utilizing the open circuit voltage-initial state of charge confidence slope, an electromotive force mapping step including mapping the open circuit voltage including electromotive force to the first state of charge and a measurement estimate update step including correcting the first state of charge utilizing the battery parameter, the Kalman gain of the error covariance prediction for the first state of charge of the battery, and the mapping the open circuit voltage to the first state of charge to provide the estimated present state of charge.

The method disclosed herein, which adaptively corrects SOC based on an elbow event in the OCV-SOC profile, may become charge-rate (C-rate) independent. The operational limits of the battery pack are thus monitored and defined on the point of interconnection (POI) of the battery pack and the fuel cell.

The method for providing an estimated present state of charge of a battery pack may use a type of non-linear observer, such as an adaptive extended Kalman filter (AEKF), to perform both estimation and correction of the SOC. The estimation stages of the method may involve a state prediction and an error covariance prediction. A correction stage may involve an observation matrix update, a Kalman gain calculation, EMF mapping, and a measurement estimate update.

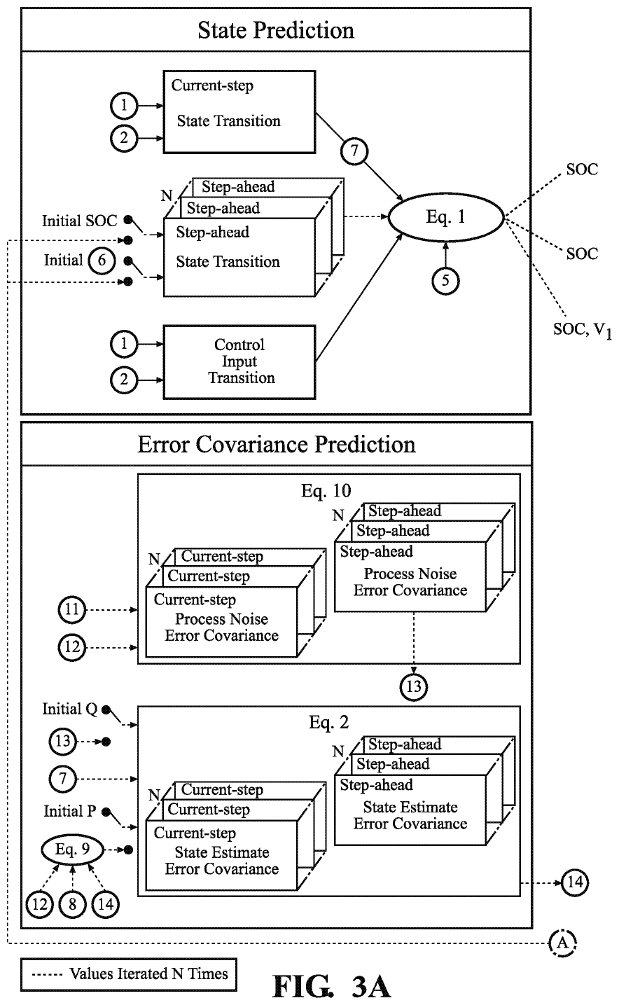

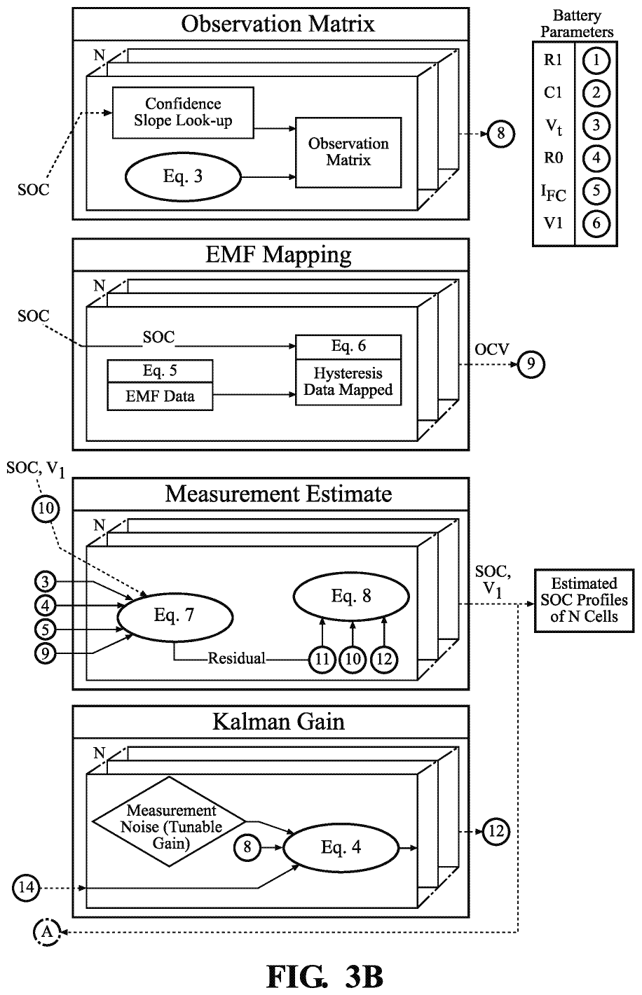

Initially, the battery's dynamics are modeled using a 1-RC or Thevenin battery model as shown in FIG. 5. The ohmic resistance (R0), RC pair's resistance (R1) and capacitance (C1), voltage across the RC pair (V₁), terminal voltage (Vₜ), and the fuel cell output current (I_{FC}) values may be used to build the state transition and control input transition for the state prediction step, and to update the measurement estimate during the correction stage. The formulations corresponding to each of these stages are shown below in equations 1 through 10 while a schematic diagram further illustrating each of the stages of the method is shown in FIGS. 3A and 3B. Implementations of the equation numbers referenced herein are identified in the schematic diagram of FIGS. 3A and 3B that illustrate aspects of the method shown FIGS. 2A-2B.

As described herein, the method may include two stages, an estimation stage and a correction stage. The estimation stage may include a state prediction step and an error covariance prediction step.

In the state prediction step, the following state vector:

$$\hat{x} = [ \begin{matrix}SOC \\ {V}_{1}\end{matrix} ] ,$$

is defined, where the battery's SOC ranges from 0 to 100%, and V₁ is obtained from the battery model. These parameters (SOC and V₁) may be re-written in respective state-space forms as:

$$\begin{matrix}{SOC}_{k + 1 \vert k} = {SOC}_{k \vert k} - η \frac{Δ t}{{C}_{max}} {I}_{{FC}_{k}^{′}} \\ {V}_{1 , k + 1 \vert k} = {e}^{- \frac{Δ t}{{R}_{1} {C}_{1}}} {V}_{1 , k \vert k} + {R}_{1} ( 1 - {e}^{- \frac{Δ t}{{R}_{1} {C}_{1}}} ) {I}_{{FC}_{k}}\end{matrix}$$

Here, I_{FCk} is the current-step current output from the fuel cell, Δt is the time interval between two current values, Cₘₐₓ is the battery's nominal capacity, η is the battery's coulombic efficiency, SOC_{k|k} is the current-step SOC which is provided with an initial SOC value, SOC_{k+1|k} is the step-ahead SOC computed using the conventional coulomb counting approach, V_{1,k|k} is the current-step V₁ which is provided with an initial V₁ value, V_{1,k+1|k} is the step-ahead RC pair voltage.

To take into account the state transition and control input transition in the AEKF, the state prediction step combines these transitions using the following step-ahead formulation: \hat{x}_{k+1|k}=A\hat{x}_{k|k}+Buₖ, which may be re-written in matrix form, as shown in Eq. 1, to include the battery model parameters.

$${[ \begin{matrix}SOC \\ {V}_{1}\end{matrix} ]}_{k + 1 \vert k} = {[ \begin{matrix}1 & 0 \\ 0 & {e}^{- \frac{Δ t}{{R}_{1} {C}_{1}}}\end{matrix} ] [ \begin{matrix}SOC \\ {V}_{1}\end{matrix} ]}_{k \vert k} + [ \begin{matrix}- η \frac{Δ t}{{C}_{max}} \\ {R}_{1} ( 1 - {e}^{- \frac{Δ t}{{R}_{1} {C}_{1}}} )\end{matrix} ] {I}_{{FC}_{k}} \qquad Eq . 1$$

State Transition Matrix:

$$A = [ \begin{matrix}1 & 0 \\ 0 & {e}^{- \frac{Δ t}{{R}_{1} {C}_{1}}}\end{matrix} ]$$

Control input Transition Matrix:

$$B = [ \begin{matrix}- η \frac{Δ t}{{C}_{max}} \\ {R}_{1} ( 1 - {e}^{- \frac{Δ t}{{R}_{1} {C}_{1}}} )\end{matrix} ]$$

During the error covariance prediction step, the state estimate uncertainty (error covariance) is modeled based on Eq. 2, which combines the measurement uncertainty with process noise.

$${P}_{k + 1 \vert k} = A {P}_{k \vert k} {A}^{T} + Q \qquad Eq . 2$$

where, P_{k|k} is the current-step measurement uncertainty, Q is the minimal process noise, generally gaussian, introduced by the battery current sensor measurements and other similar data acquisition sources, P_{k+1|k} is the step-ahead measurement uncertainty applied on the state transition matrix. During this step, the process noise error covariance gets recursively updated based on Eqs. 9 and 10 discussed herein below.

The correction stage includes the steps of an observation matrix update, a Kalman Gain, an EMF Mapping, and a measurement estimate update.

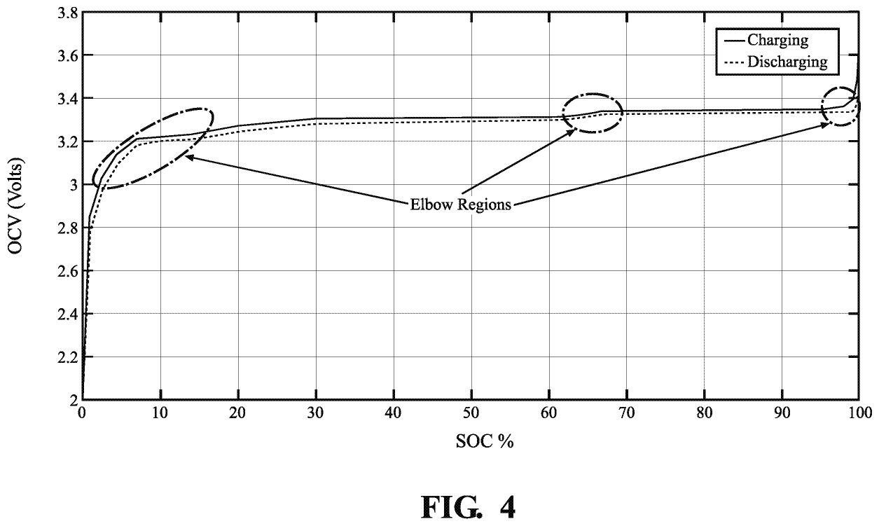

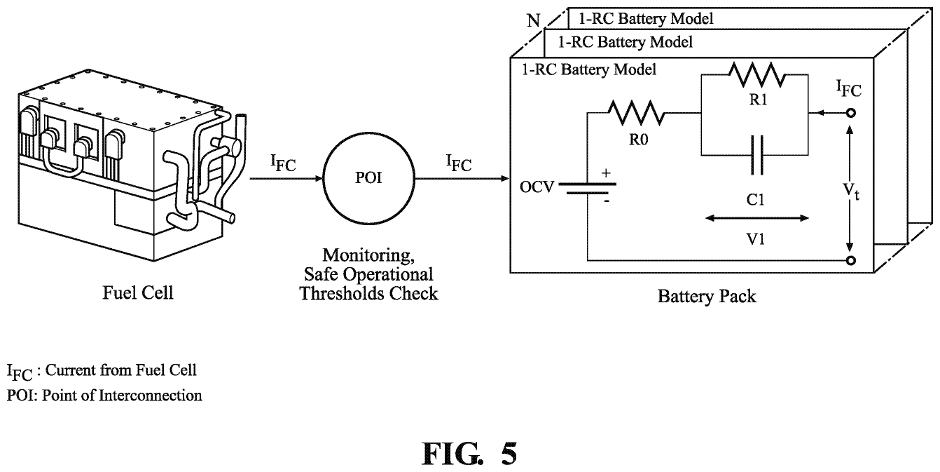

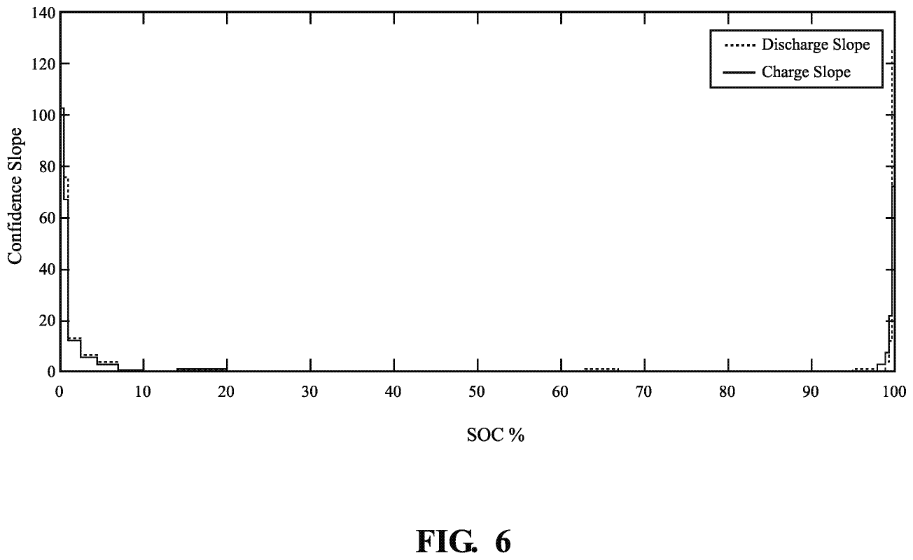

In the observation matrix step, the observation or Jacobian matrix allows mapping of SOC to the measured values (OCV-SOC slope), using the OCV-SOC confidence slope. The confidence slope shown in FIG. 6 allows identification of the elbow regions and is obtained by identifying values from the original OCV-SOC values shown in FIG. 4, as shown below in Eq. 3.

$$\begin{matrix}c ( SOC , {V}_{1} ) OCV ( SOC ) - {V}_{1} - {R}_{0} {I}_{F C} \\ \frac{\partial c}{\partial {V}_{1}} = \frac{\partial ( OCV ( SOC ) - {V}_{1} - {R}_{0} {I}_{F C} )}{\partial {V}_{1}} = - 1 \\ C = J ( c ( x ) ) = [ \frac{\partial c}{\partial SOC} \frac{\partial c}{\partial {V}_{1}} ] = [ \frac{dOCV}{dSOC} - 1 ]\end{matrix} \qquad Eq . 3$$

Here, c(SOC,V₁) is a non-linear function representing Vₜ as the function of states. C=J(c(x)) is the Jacobian or observation matrix constituting confidence slopes of OCV and V₁ with respect to SOC. The resulting Jacobian values get recursively updated as the SOC values change.

In the Kalman Gain step, the changing Jacobian (C) values, step-ahead measurement uncertainty (P_{k+1|k}), and a tunable measurement noise introduced by the equipment, predominantly due to measurements of Vₜ, formulate the Kalman gain as shown in Eq. 4.

$${K}_{k + 1} = {P}_{k + 1 \vert k} {{C}^{T} ( R k + 1 + {C}_{P k + 1 \vert k} {C}^{T} )}^{- 1} \qquad Eq . 4$$

where, Rₖ₊₁ is the measurement noise introduced during the step-ahead measurements.

In the EMF Mapping step, SOC_{k+1|k} from the state prediction step is mapped to OCV recursively for every EMF-SOC value. The EMF values are obtained from a combination of major and minor hysteresis models, as shown in Eq. 5.

$$H = {Φ}_{minor} \frac{{I}_{FC} Δ t}{{C}_{max} + {ε}_{minor}} + {Φ}_{major} \frac{{I}_{FC} Δ t}{{C}_{max} + {ε}_{major}} \qquad Eq . 5$$

where, ϕₘᵢₙₒᵣ and ϕₘₐⱼₒᵣ are minor and major hysteresis factors respectively, and εₘᵢₙₒᵣ and εₘₐⱼₒᵣ are minor and major hysteresis ratios respectively. The resulting EMF characteristic is then interpolated to OCV based on the formulation shown in Eq. 6.

$$O C V ( S O C , H ) = H . {OCV}_{charge} ( SOC ) + ( 1 - H ) {OCV}_{discharge} ( SOC ) \qquad Eq . 6$$

In the measurement estimate step, Vₜ, R0, I_{FCk}, V_{1,k+1|k}, and OCV(SOC,H) are used to calculate error in the terminal voltage computed using the model and actual reading from the battery, as shown in Eq. 7. This error, termed as “residual”, is used to recursively update the process noise error covariance.

$${\hat{y}}_{k + 1} = {V}_{t , k + 1} - ( OCV ( SOC , H ) - V 1 - {R}_{0} i ) \qquad Eq . 7$$

Using a measurement estimate consisting of residual and Kalman gain, the state estimate is updated by Eq. 8.

$${[ \begin{matrix}SOC \\ {V}_{1}\end{matrix} ]}_{k + 1 \vert k + 1} = {[ \begin{matrix}SOC \\ {V}_{1}\end{matrix} ]}_{k + 1 \vert k} + {K}_{k + 1} {\hat{y}}_{k + 1} \qquad Eq . 8$$

The resulting SOC_{k+1|k+1} is an estimated SOC value, which when recursively updated provides the complete estimated SOC profile of a cell in a battery pack.

In the error covariance update step, the error covariance prediction values, P_{k+1|k} along with Kₖ₊₁, and C are used to update P_{k|k} for step-ahead error covariance state estimate, using Eq. 9.

$${P}_{k + 1 \vert k + 1} = ( I - {K}_{k + 1} C ) {P}_{k + 1 \vert k} \qquad Eq . 9$$

In addition, the process noise error covariance (Q) gets updated using Kₖ₊₁, and ŷₖ₊₁, as shown in Eq. 10, and is used to further update step-ahead error covariance state estimate.

$$Q = {K}_{k + 1} {\hat{y}}_{k + 1} {K}_{k + 1}^{T} \qquad Eq . 10$$

As a result, Eqs. 9 and 10 introduce the self-correcting (adaptive) feature in the extended Kalman filter. The overall process is repeated for every cell in the battery pack connected to the BMS.

The schematic diagram in FIG. 3A and FIG. 3B represent the data flow through each of the above-mentioned steps. This diagram shows the specific steps that may allow scaling up of the estimation method to N number of cells in a battery pack, hence, resulting in visualization of the estimated SOC of each cell in a battery pack.

It is noted that generally, individual cells of same chemistry and rating are interconnected to form a pack and to connect with the battery management system (BMS). In cases where the chemistry of respective battery cells is varied (with safe operational thresholds at POI), and as a result, the model of the internal parameters of the battery vary, the method accordingly provides high fidelity results as the battery model parameters themselves are iterated over each cell and thus incorporate the varying dynamics of the various batteries internal parameters.

### Examples

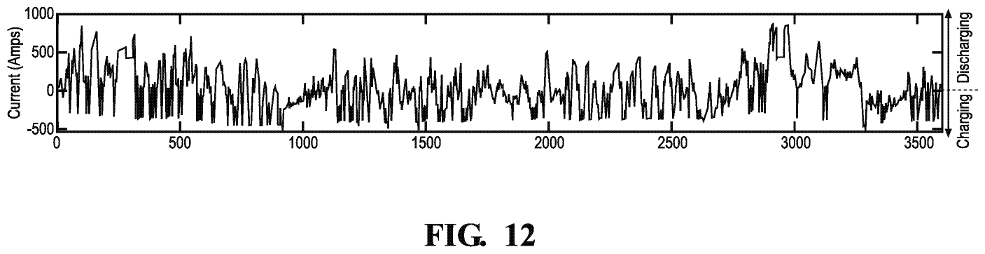

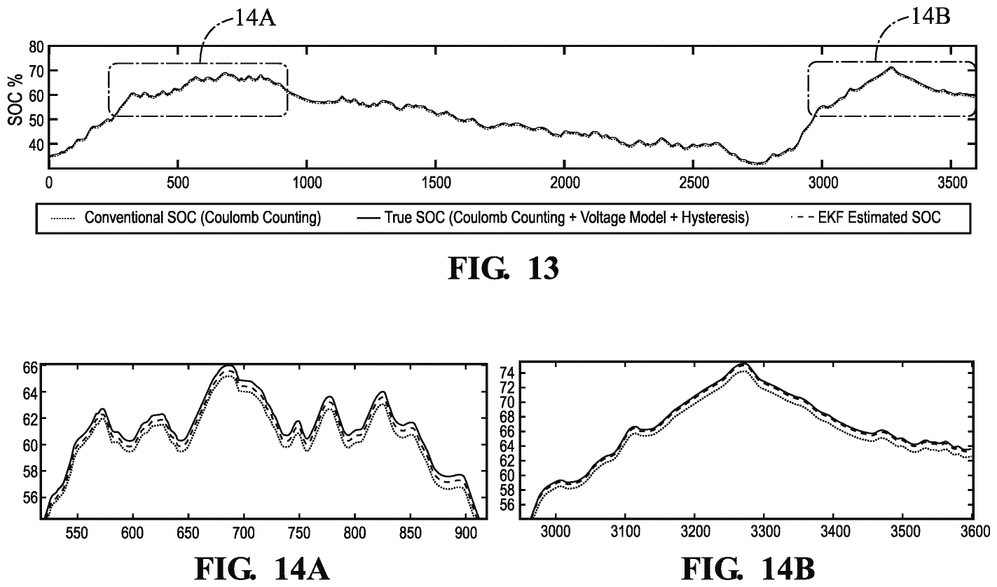

Models of the methodology and formulations of the present method were constructed, and results shown within FIGS. 12-20 and herein below verify the improved estimated SOC for a cell in a battery pack. Specifically, a first method was modeled which takes voltage model (from 1-RC battery model) and hysteresis into account, along with coulomb counting (the “Conventional SOC” method). This method is termed as the “True SOC” method. The second method modeled uses the AEKF estimated SOC (labelled as “EKF Estimated SOC” method) disclosed herein. The following three case studies show the comparison of the performance of the respective models in terms of the error accumulated over time, with respect to the True SOC method.

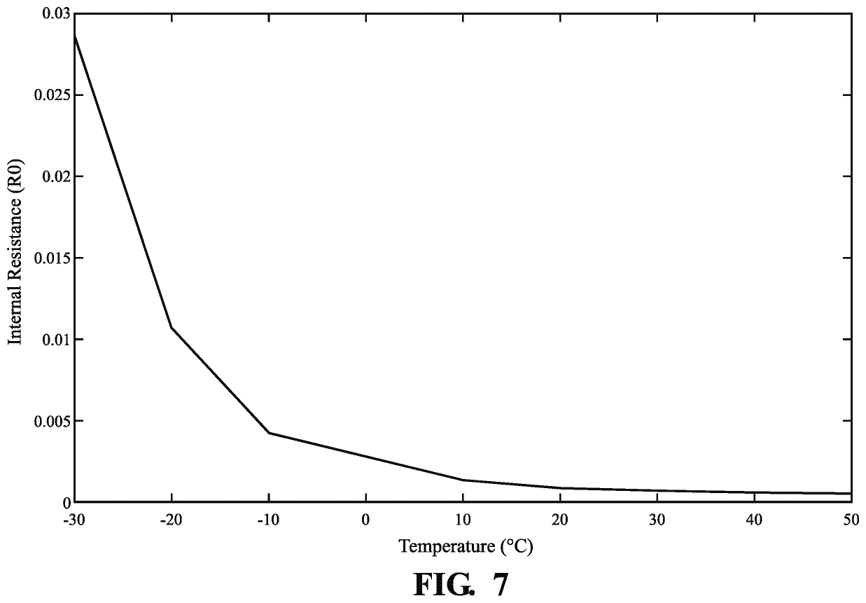

For each of the case studies, the following Table identifies the parameters and values used in the models of both the first and second method.

| Tunable Parameters | Values |
|---|---|
| Initial SOC | Varied based on cases. |
| Initial V₁ | 0 V |
| Φₘᵢₙₒᵣ | 0.8 |
| Φₘₐⱼₒᵣ | 0.2 |
| εₘᵢₙₒᵣ | 0.05 |
| εₘₐⱼₒᵣ | 0.2 |
| R0 | Plotted in |
| R1 | FIGS. 7, 8, and 9. |
| C1 | |
| I_{FC}_{ₖ} | Current profiles obtained |
| | from existing drive |
| | cycles based on trials. |
| Initial P | [10⁻⁴, 0; 0, 10⁻⁴] |
| Initial Q | [0, 0; 0, 0] |
| Initial R | 0.15 |

In Case 1, as shown within FIGS. 12-15 an initial SOC was set at 35%. These figures show the graphic outputs from the models and compare the accumulated error profile of the True SOC method to the improved AEKF estimated SOC disclosed herein.

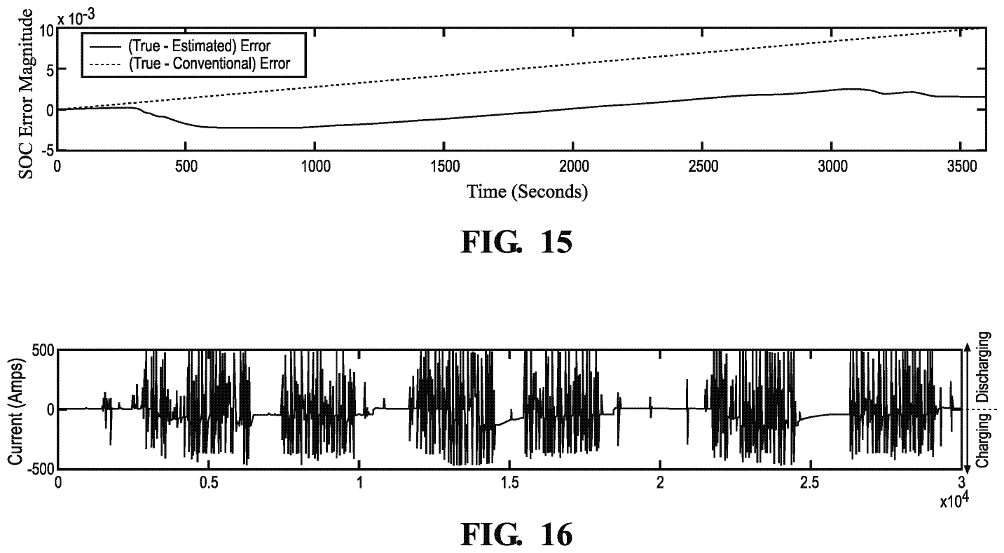

Case 1 Analysis: With Current profile A (shown in FIG. 12) applied with initial SOC set to 35%, the SOC values revolve between 35%-71%. As soon as the SOC values cross the elbow region between 60%-70% SOC, the AEKF initiates correction, and this may be seen from the (True-Estimated) results in FIG. 15. After a learning delay, the AEKF corrects (and reduces error) the SOC values at the second elbow region, as shown in FIGS. 14A and 14B. On the other hand, the error corresponding to the conventional SOC method continues to increase irrespective of the elbow regions.

In Case 2, an initial SOC was set at 90%. FIGS. 16-18 show the graphic outputs from the models and compare the accumulated error profile of the True SOC method to the improved AEKF estimated SOC disclosed herein.

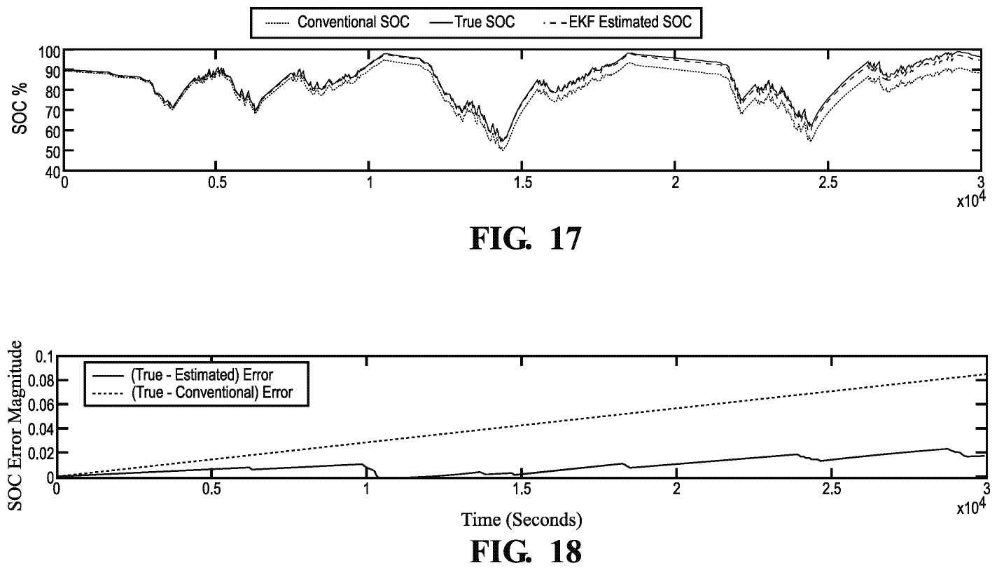

In Case 2, such as shown within FIGS. 16-18, current profile B (shown in FIG. 16) applied with initial SOC set to 90%, the SOC values revolve between 50%-100%. As soon as the SOC values cross the elbow regions between 60%-70% SOC and above 95% SOC, the AEKF initiates correction, and this may be seen from the (True-Estimated) results in FIG. 18. After a learning delay, the AEKF corrects (and reduces error at) the SOC values at the second elbow region, as shown in FIG. 17. On the other hand, the error corresponding to the conventional coulomb counting approach continues to increase irrespective of the elbow regions.

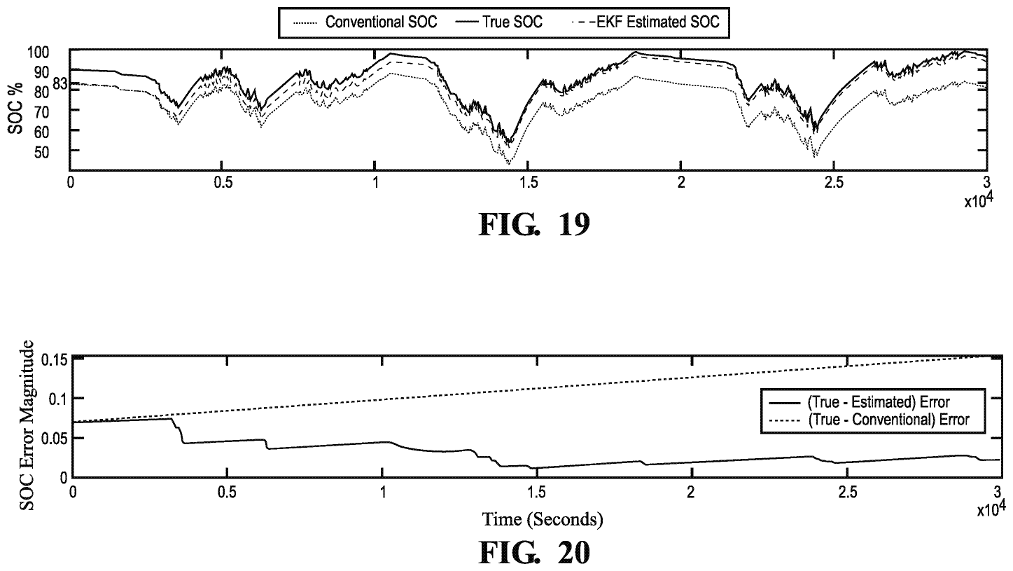

In Case 3, such as shown within FIGS. 19-20, different initial SOCs were employed (an SOC mismatch scenario), wherein SOC was set at 90% for the True SOC method, and 83% for the AEKF estimated SOC. The figures below show the graphic outputs from the models and compare the accumulated error profile of the True SOC method to the improved AEKF estimated SOC disclosed herein.

Case 3 Analysis: With Current profile B (shown in Case 2-FIG. 16) applied under initial SOC mismatch scenario to evaluate the correction capability of the AEKF estimated SOC when the model is provided with incorrect initial SOC value. The AEKF appears to correct the SOC values after crossing elbow regions multiple times (with delay), as may be seen in FIG. 19. The corresponding accumulated error stabilizes around 0.025 in case of the AEKF estimated SOC but continues to increase for the conventional SOC method, irrespective of the elbow regions. This may be seen in FIG. 20.

The present technology improves the estimated charge of a batter pack by providing a SOC estimation and correction approach that makes the battery charging (and state estimation) charge-rate independent and scales up the methodology for all the cells in a battery pack irrespective of the interconnection configuration, and improves the estimation fidelity by using self-correcting state approach for every cell in a pack.

In certain embodiments, the present method for technology provides an estimated present state of charge of a battery pack to overcome the error accumulation and delayed charging scenarios in a fuel cell electric vehicle. The method, which adaptively corrects the SOC based on an elbow event in the OCV-SOC profile, becomes C-rate independent. The safe operational limits of the battery pack are thus monitored and defined on the POI of the battery pack and the fuel cell.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms, and that neither should be construed to limit the scope of the disclosure. In some example embodiments, well-known processes, well-known device structures, and well-known technologies are not described in detail. Equivalent changes, modifications and variations of some embodiments, materials, compositions and methods can be made within the scope of the present technology, with substantially similar results.

What is claimed is:

1. A method for providing an estimated present state of charge of a battery, comprising:
measuring a battery parameter including an open circuit voltage;
performing an estimation stage including:
a state prediction step including calculating a first state of charge of the battery utilizing an initial state of charge of the battery and the battery parameter;
an error covariance step including calculating an error covariance prediction for the first state of charge of the battery; and
performing a correction stage including:
an observation matrix update step including mapping the open circuit voltage of the battery to the initial state of charge of the battery to obtain an open circuit voltage-initial state of charge confidence slope;
a Kalman gain step including calculating a Kalman gain of the error covariance prediction for the first state of charge of the battery utilizing the open circuit voltage-initial state of charge confidence slope;
an electromotive force mapping step including mapping the open circuit voltage including electromotive force to the first state of charge;
a measurement estimate update step including correcting the first state of charge utilizing the battery parameter, the Kalman gain of the error covariance prediction for the first state of charge of the battery, and the mapping the open circuit voltage to the first state of charge to provide the estimated present state of charge.

2. The method of claim 1, wherein the battery parameter includes a member selected from a group consisting of: an ohmic resistance, a resistor-capacitor pair resistance, a resistor-capacitor pair capacitance, a voltage across a resistor-capacitor pair, a terminal voltage, a fuel cell output current, and combinations thereof.

3. The method of claim 1, wherein the battery parameter includes three members selected from a group consisting of: an ohmic resistance, a resistor-capacitor pair resistance, a resistor-capacitor pair capacitance, a voltage across a resistor-capacitor pair, a terminal voltage, and a fuel cell output current.

4. The method of claim 1, wherein the battery parameter includes an ohmic resistance, a resistor-capacitor pair resistance, a resistor-capacitor pair capacitance, a voltage across a resistor-capacitor pair, a terminal voltage, and a fuel cell output current.

5. The method of claim 1, further comprising updating the error covariance prediction for the first state of charge of the battery utilizing the Kalman gain.

6. The method of claim 1, further comprising utilizing the estimated present state of charge of the battery as the initial state of charge of the battery in a subsequent iteration of the method for providing a subsequent estimated present state of charge of the battery.

7. The method of claim 1, further comprising utilizing the estimated present state of charge of the battery as the initial state of charge of the battery in a plurality of iterations of the method for providing an updated estimated present state of charge of the battery based upon the plurality of iterations.

8. The method of claim 1, wherein the battery includes a plurality of battery cells, and the method is utilized to provide an estimated present state of charge for each battery cell of the plurality of battery cells.

9. The method of claim 8, wherein the estimated present state of charge for each battery cell of the plurality of battery cells is averaged to provide the estimated present state of charge of the battery.

10. The method of claim 1, further comprising:
updating the error covariance prediction utilizing the Kalman gain; and
utilizing the estimated present state of charge as the initial state of charge in a subsequent iteration of the method for providing the estimated present state of charge.

11. An electrical storage system comprising:
a battery pack including a battery;
a sensor in electrical communication with the battery and configured to measure an electrical parameter of the battery; and
a controller in electrical communication with the sensor, the controller configured to:
perform an estimation stage including:
a state prediction step including calculating a first state of charge of the battery utilizing an initial state of charge of the battery and the battery parameter;
an error covariance step including calculating an error covariance prediction for the first state of charge of the battery; and
perform a correction stage including:
an observation matrix update step including mapping an open circuit voltage of the battery to the initial state of charge of the battery to obtain an open circuit voltage-initial state of charge confidence slope;
a Kalman gain step including calculating a Kalman gain of the error covariance prediction for the first state of charge of the battery utilizing the open circuit voltage-initial state of charge confidence slope;
an electromotive force mapping step including mapping the open circuit voltage including electromotive force to the first state of charge;
a measurement estimate update step including correcting the first state of charge utilizing the battery parameter, the Kalman gain of the error covariance prediction for the first state of charge of the battery, and the mapping the open circuit voltage to the first state of charge to provide an estimated present state of charge.

12. The electrical storage system of claim 11, wherein the battery parameter includes a member selected from a group consisting of: an ohmic resistance, a resistor-capacitor pair resistance, a resistor-capacitor pair capacitance, a voltage across a resistor-capacitor pair, a terminal voltage, a fuel cell output current, and combinations thereof.

13. The electrical storage system of claim 11, wherein the battery parameter includes three members selected from a group consisting of: an ohmic resistance, a resistor-capacitor pair resistance, a resistor-capacitor pair capacitance, a voltage across a resistor-capacitor pair, a terminal voltage, and a fuel cell output current.

14. The electrical storage system of claim 11, wherein the battery parameter includes an ohmic resistance, a resistor-capacitor pair resistance, a resistor-capacitor pair capacitance, a voltage across a resistor-capacitor pair, a terminal voltage, and a fuel cell output current.

15. The electrical storage system of claim 11, further comprising updating the error covariance prediction for the first state of charge of the battery utilizing the Kalman gain.

16. The electrical storage system of claim 11, further comprising utilizing the estimated present state of charge of the battery as the initial state of charge of the battery in a subsequent iteration for providing a subsequent estimated present state of charge of the battery.

17. The electrical storage system of claim 11, further comprising utilizing the estimated present state of charge of the battery as the initial state of charge of the battery in a plurality of iterations for providing an updated estimated present state of charge of the battery based upon the plurality of iterations.

18. The electrical storage system of claim 11, wherein the battery includes a plurality of battery cells, and wherein an estimated present state of charge is provided for each battery cell of the plurality of battery cells.

19. The electrical storage system of claim 18, wherein the estimated present state of charge for each battery cell of the plurality of battery cells is averaged to provide the estimated present state of charge of the battery.

20. A method for providing an estimated present state of charge of a battery pack, comprising:
Measuring electrical parameters of a plurality of battery cells of the battery pack, the electrical parameters of the plurality of battery cells including an open circuit voltage, an ohmic resistance, a RC pair resistance, a RC pair capacitance, a voltage across a RC pair, a terminal voltage, and a fuel cell output current;
calculating a first state of charge for each battery cell of the plurality of battery cells utilizing an initial state of charge and the electrical parameters;
calculating an error covariance prediction for the first state of charge of each battery cell of the plurality of battery cells;
calculating an estimated present state of charge of each battery cell of the plurality of battery cells by:
mapping the open circuit voltage to the initial state of charge to obtain an open circuit voltage-initial state of charge confidence slope,
calculating a Kalman gain of the error covariance prediction utilizing the open circuit voltage-initial state of charge confidence slope,
mapping the open circuit voltage (incorporating EMF) to the first state of charge, and
correcting the first state of charge of each battery cell of the plurality of battery cells by utilizing selected ones of the electrical parameters, and the Kalman gain, and a mapping of a resulting voltage to the first state of charge to provide the estimated present state of charge of each battery cell of the plurality of battery cells;
averaging the estimated present state of charge for each battery cell of the plurality of battery cells to provide an estimated present state of charge of the battery pack;
updating the error covariance prediction for each battery cell of the plurality of battery cells utilizing the Kalman gain; and
utilizing the estimated present state of charge of each battery cell of the plurality of battery cells as the initial state of charge in a subsequent iteration of the method to provide the estimated present state of charge for the battery pack.
